(19) United States
(12) Patent Application Publication
(10) Pub. No.: US 2026/0132542 A1
(43) Pub. Date: May 14, 2026

(54) SINGLE-CRYSTAL DIAMOND SUBSTRATE WITH TWIN DEFECTS REMOVED AND METHOD FOR MANUFACTURING THE SAME

(71) Applicant: TECH UNIVERSITY OF KOREA Industry Academic Cooperation Foundation, Siheung-si (KR)

(72) Inventors: Okhyun NAM, Seoul (KR); Hyeonu KANG, Incheon (KR); Uiho CHOI, Seoul (KR); Geunho YOO, Incheon (KR); Jongbeom LEE, Seoul (KR); Yeonghwa KWON, Seoul (KR); Taemyung KWAK, Seoul (KR)

(21) Appl. No.: 18/863,613

(22) PCT Filed: Jun. 3, 2024
(86) PCT No.: PCT/KR2024/007544

§ 371 Date: Nov. 6, 2024

(51) Int. Cl. C30B 25/18; C30B 29/04

(52) U.S. Cl. CPC C30B 25/183; C30B 29/04

(57) ABSTRACT

The present invention relates to a single-crystal diamond substrate with twin defects removed and a method for manufacturing the same, and more particularly, to a single-crystal diamond substrate with twin defects removed and a method for manufacturing the same, in which a buffer layer including an Ir metal layer is arranged on a top surface of a base layer including an R-plane sapphire substrate, so that a single-crystal diamond substrate in which a defect of the substrate is controlled and including a single-crystal diamond layer oriented in a (111) direction and a method for manufacturing the single-crystal diamond substrate are provided.

### TECHNICAL FIELD

The present invention relates to a single-crystal diamond substrate with twin defects removed and a method for manufacturing the same, and more particularly, to a single-crystal diamond substrate with twin defects removed and a method for manufacturing the same, in which a buffer layer including an Ir metal layer is arranged on a top surface of a base layer including an R-plane sapphire substrate, so that a single-crystal diamond substrate in which a defect of the substrate is controlled and including a single-crystal diamond layer oriented in a (111) direction and a method for manufacturing the single-crystal diamond substrate are provided.

### BACKGROUND ART

Recently, a technology for manufacturing a semiconductor element by using a single-crystal diamond as a substrate material is being disclosed. A single-crystal diamond substrate is a substrate material capable of manufacturing a semiconductor element having an ultra-wide band gap (UWBG), and the semiconductor element adopting the single-crystal diamond substrate may have improved energy efficiency and implement miniaturization and weight reduction of semiconductor elements so that next-generation power elements for electric vehicles, ultra-high frequency communications, quantum sensors, and the like may be produced. Accordingly, a technology for manufacturing a high-quality single-crystal diamond substrate is required.

A diamond semiconductor element substrate oriented in a (111) direction has excellent doping efficiency and quantum characteristics as compared with a substrate oriented in a (001) direction. Accordingly, the diamond semiconductor element substrate oriented in the (111) direction may be suitable for manufacturing high-performance electronic devices and quantum sensors, whereas the substrate is highly likely to have substrate defects upon formation.

In other words, there is a need for a technology about a single-crystal diamond substrate in which the single-crystal diamond substrate having an UWBG so as to be used as a substrate for a next-generation semiconductor element is oriented in a (111) direction and a defect of the substrate is controlled, and a method for manufacturing the single-crystal diamond substrate.

### DISCLOSURE

### Technical Problem

An object of the present invention is to provide a single-crystal diamond substrate with twin defects removed and a method for manufacturing the same, in which a buffer layer including an Ir metal layer may be arranged on a top surface of a base layer including an R-plane sapphire substrate, so that a single-crystal diamond substrate in which a defect of the substrate is controlled and including a single-crystal diamond layer oriented in a (111) direction and a method for manufacturing the single-crystal diamond substrate may be provided.

### Technical Solution

To achieve the object described above, according to one embodiment of the present invention, there is provided a single-crystal diamond substrate in which a defect of the substrate is controlled, the single-crystal diamond substrate including: a base layer; a buffer layer formed on the base layer; and a single-crystal diamond layer formed on the buffer layer, wherein the base layer includes a sapphire substrate, the sapphire substrate has an R-plane oriented in a preset direction, and the buffer layer includes an Ir metal layer.

According to some embodiments of the present invention, the single-crystal diamond substrate may have three peaks spaced apart from each other at an interval of 120 degrees on an X-ray diffraction pole figure.

According to some embodiments of the present invention, the single-crystal diamond substrate may control a twin defect generated upon the formation of the single-crystal diamond layer.

According to some embodiments of the present invention, the single-crystal diamond substrate may further include: a preliminary diamond layer formed on the buffer layer, wherein the single-crystal diamond layer may be formed on the preliminary diamond layer, and the preliminary diamond layer may have a thickness that is thinner than a thickness of the single-crystal diamond layer.

According to some embodiments of the present invention, the single-crystal diamond substrate may have a form in which the single-crystal diamond layer is separated from the base layer after the base layer, the buffer layer, and the single-crystal diamond layer are consecutively formed.

According to some embodiments of the present invention, the buffer layer may include the Ir metal layer oriented in a (111) direction.

According to some embodiments of the present invention, the buffer layer may have a thickness of 20 nm to 1 μm.

According to some embodiments of the present invention, the single-crystal diamond layer may be grown while being oriented in a plane direction corresponding to a plane direction of the buffer layer, and the single-crystal diamond substrate may control a defect of the substrate by the buffer layer and the single-crystal diamond layer, which are oriented in the plane directions corresponding to each other.

According to some embodiments of the present invention, the single-crystal diamond layer may include a single-crystal diamond layer oriented in the (111) direction.

To achieve the object described above, according to one embodiment of the present invention, there is provided a method for manufacturing a single-crystal diamond substrate in which a defect of the substrate is controlled, the method including: a base layer preparation step of preparing a base layer; a buffer layer formation step of forming a buffer layer on the base layer; and a single-crystal diamond layer formation step of forming a single-crystal diamond layer on the buffer layer, wherein the base layer includes a sapphire substrate, the sapphire substrate has an R-plane oriented in a preset direction, and the buffer layer includes an Ir metal layer.

According to some embodiments of the present invention, the single-crystal diamond substrate may have three peaks spaced apart from each other at an interval of 120 degrees on an X-ray diffraction pole figure.

According to some embodiments of the present invention, the single-crystal diamond substrate may control a twin defect generated upon the formation of the single-crystal diamond layer.

To achieve the object described above, according to one embodiment of the present invention, there is provided a method for manufacturing a single-crystal diamond substrate in which a defect of the substrate is controlled, the method including: a base layer preparation step of preparing a base layer; a buffer layer formation step of forming a buffer layer on the base layer; a preliminary diamond layer formation step of forming a preliminary diamond layer on the buffer layer; and a single-crystal diamond layer formation step of forming a single-crystal diamond layer on the preliminary diamond layer, wherein the base layer includes a sapphire substrate, the sapphire substrate has an R-plane oriented in a preset direction, and the buffer layer includes an Ir metal layer.

According to some embodiments of the present invention, the single-crystal diamond substrate may have three peaks spaced apart from each other at an interval of 120 degrees on an X-ray diffraction pole figure.

According to some embodiments of the present invention, the single-crystal diamond substrate may control a twin defect generated upon the formation of the single-crystal diamond layer.

### Advantageous Effects

According to one embodiment of the present invention, a buffer layer including an Ir metal layer may be arranged on a top surface of an R-plane sapphire substrate, and a single-crystal diamond layer may be formed on a top surface of the buffer layer, so that a defect of a single-crystal diamond substrate oriented in a (111) direction can be controlled so as to improve quality. According to one embodiment of the present invention, an Ir metal layer may be formed on a top surface of an R-plane sapphire substrate, so that a defect of the Ir metal layer can be controlled.

According to one embodiment of the present invention, a single-crystal diamond layer may be grown on a top surface of a buffer layer in which a defect of a substrate is controlled, so that a defect of the single-crystal diamond

layer can be controlled. According to one embodiment of the present invention, each of top surfaces of a buffer layer and a single-crystal diamond layer may be oriented in a (111) direction so as to allow shapes of atoms arranged on the top surfaces to correspond to each other, so that residual stress of the single-crystal diamond layer caused by a difference in lattice constants and thermal expansion coefficients between the single-crystal diamond layer and a base layer can be minimized so as to improve durability of a single-crystal diamond substrate.

According to one embodiment of the present invention, a preliminary diamond layer that serves as a seed of a diamond layer may be formed on a top surface of a buffer layer, so that a yield of the single-crystal diamond layer can be increased.

According to one embodiment of the present invention, a single-crystal diamond substrate may be configured such that a single-crystal diamond layer may be separated from a base layer, so that the single-crystal diamond layer can be easily provided.

### DESCRIPTION OF DRAWINGS

FIG. 1 is a schematic diagram showing a single-crystal diamond substrate according to one embodiment of the present invention.

FIG. 2A and FIG. 2B show details of a lattice structure of a sapphire substrate according to one embodiment of the present invention.

FIG. 3A and FIG. 3B show details of a lattice structure of iridium (Ir) and diamond according to one embodiment of the present invention.

FIG. 4 shows details of X-ray diffraction patterns of a base layer and a buffer layer according to one embodiment of the present invention.

FIG. 5 shows details of an X-ray diffraction pole figure according to one embodiment of the present invention. FIG. 6A and FIG. 6B schematically show details of a known twin defect.

FIG. 7 schematically shows a method for manufacturing a single-crystal diamond substrate according to one embodiment of the present invention.

FIG. 8A, FIG. 8B, and FIG. 8C schematically show an embodiment of performing each step of the method for manufacturing the single-crystal diamond substrate according to one embodiment of the present invention.

FIG. 9 schematically shows a method for manufacturing a single-crystal diamond substrate according to another embodiment of the present invention.

FIG. 10A, FIG. 10B, FIG. 10C, and FIG. 10D schematically show an embodiment of performing each step of the method for manufacturing the single-crystal diamond substrate according to another embodiment of the present invention.

### MODE OF INVENTION

Hereinafter, various embodiments and/or aspects will be disclosed with reference to the drawings. In the following description, for the purpose of description, numerous specific details are set forth in order to facilitate an overall understanding of one or more aspects. However, it will also be appreciated by a person having ordinary skill in the art to which the present invention pertains that such aspect(s) may be practiced without the specific details. The following description and the accompanying drawings will be set forth in detail for specific illustrative aspects among the one or more aspects. However, the aspects are provided for illustrative purposes, some of various schemes based on principles of various aspects may be employed, and descriptions set forth herein are intended to include all the aspects and equivalents thereof.

In addition, various aspects and features will be proposed by a system that may include a plurality of devices, components, and/or modules. It will also be understood and appreciated that various systems may include additional devices, components, and/or modules, and/or that various systems may not include all of the devices, components, modules, and the like discussed in association with the drawings.

The terms “embodiment”, “example”, “aspect”, “illustration”, and the like used herein may not be construed as indicating that any aspect or design set forth herein is preferable or advantageous over other aspects or designs.

In addition, it is to be understood that the terms “include” and/or “comprise” indicate the presence of corresponding features and/or elements, but do not preclude the presence or addition of one or more other features, elements, and/or groups thereof.

In addition, although the terms including ordinal numbers such as “first” and “second” may be used to describe various elements, the elements are not limited by the terms. The above terms are used merely for the purpose of distinguishing one element from another element. For example, a first element may be termed as a second element, and similarly, a second element may also be termed as a first element without departing from the scope of the present invention. The term “and/or” includes any combination of a plurality of described relevant items, or one of the described relevant items.

In addition, unless defined otherwise, all terms used in embodiments of the present invention, including technical and scientific terms, have the same meaning as those commonly understood by a person having ordinary skill in the art to which the present invention pertains. Any terms as those defined in generally used dictionaries are to be interpreted to have the meanings consistent with the contextual meanings in the relevant field of art, and are not to be interpreted to have idealistic or excessively formalistic meanings unless explicitly defined in the embodiments of the present invention.

A single-crystal diamond substrate 1 is attracting attention as a material for a next-generation semiconductor element, and in particular, a single-crystal diamond substrate 1 oriented in a (111) direction has high thermal conductivity and low defect density so as to be essential for producing high-power and high-performance electronic devices. Preferably, in order to produce a single-crystal diamond substrate 1 having a large diameter, the single-crystal diamond substrate 1 may be preferably formed by a heterogeneous growth scheme.

However, the single-crystal diamond substrate 1 oriented in the (111) direction may have a small lattice constant so that an appropriate base layer 100 may not be easily found, and in particular, defects may be easily generated in the single-crystal diamond substrate 1 oriented in the (111) direction and formed by the heterogeneous growth scheme.

In order to solve the above problems, according to the present invention, heterogeneous growth of a single-crystal diamond layer 300 has been attempted by using an Ir (iridium) metal layer oriented in a (111) direction on a top surface of an R-plane sapphire substrate.

In more detail, according to the present invention, a single-crystal diamond substrate 1 may be formed by forming the Ir metal layer on the top surface of the sapphire substrate having an R-plane (1-102) surface, and heterogeneously growing a single-crystal diamond layer 300 on the top surface.

In this case, the Ir metal layer may be preferably oriented in the (111) direction, so that the single-crystal diamond layer 300 may be oriented in the (111) direction. The (111) direction may correspond to a direction of a crystal plane represented by a Miller index of the crystal plane. In this case, the Miller index of the crystal plane may correspond to a value obtained by expressing, as a minimum integer ratio, a reciprocal of a value obtained by dividing a length of a three-dimensional coordinate axis by a unit length of the axis.

Accordingly, the defects of the single-crystal diamond layer 300 may be controlled so that a twin defect, which is a kind of defects of a substrate, may not exist or may hardly exist.

In other words, according to the present invention, a buffer layer 200 including an Ir metal layer may be arranged on a top surface of a base layer 100 including an R-plane sapphire substrate, and a single-crystal diamond layer 300 may be formed on a top surface of the buffer layer 200, so that a single-crystal diamond substrate 1 oriented in a (111) direction and in which a defect of the substrate is controlled so as to have high quality may be provided.

Hereinafter, a single-crystal diamond substrate 1 according to one embodiment of the present invention will be described in detail.

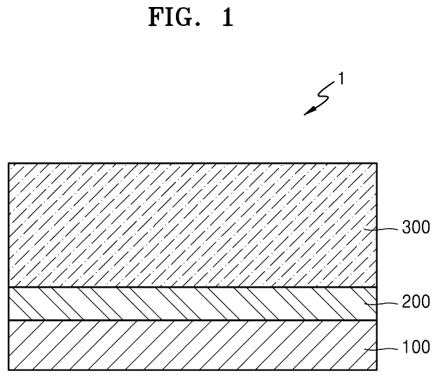

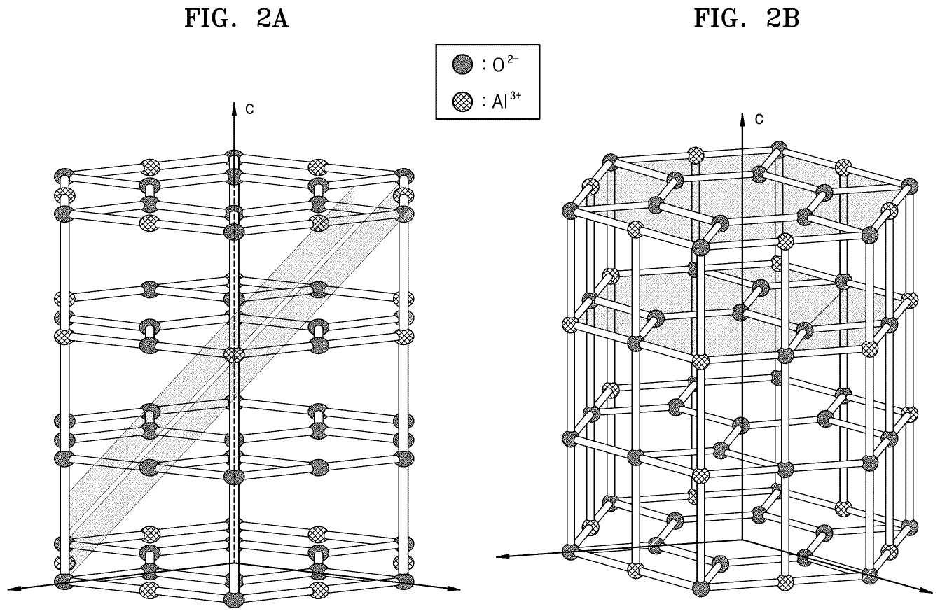

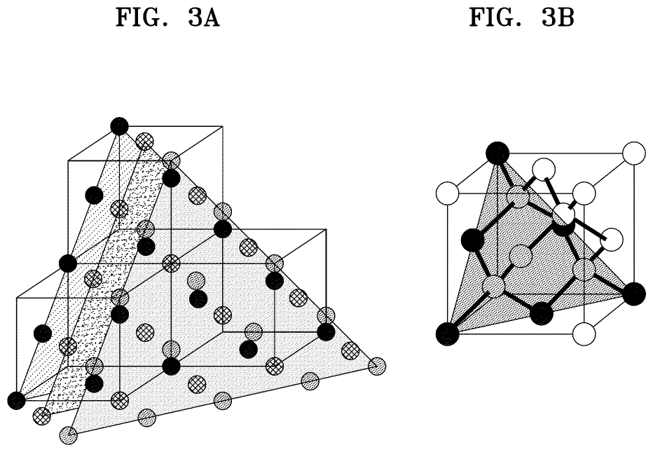

FIG. 1 is a schematic diagram showing a single-crystal diamond substrate 1 according to one embodiment of the present invention, FIG. 2A and FIG. 2B show details of a lattice structure of a sapphire substrate according to one embodiment of the present invention, and FIG. 3A and FIG. 3B show details of a lattice structure of iridium (Ir) and diamond according to one embodiment of the present invention.

As shown in FIG. 1, according to one embodiment of the present invention, a single-crystal diamond substrate 1 in which a defect of the substrate is controlled may include: a base layer 100; a buffer layer 200 formed on the base layer 100; and a single-crystal diamond layer 1 formed on the buffer layer 200. In this case, the base layer 100 may include a sapphire substrate, the sapphire substrate may have an R-plane oriented in a preset direction, and the buffer layer 200 may include an Ir metal layer.

The base layer 100 may correspond to a configuration of a base substrate for growing the single-crystal diamond layer 300, which is a configuration formed of a different component from the single-crystal diamond layer 300. According to the present invention, a heterogeneous growth scheme utilizing a heterogeneous substrate that is suitable for producing a substrate having a large diameter of 2 inches or more, which is a size that may be used as a substrate for a semiconductor element, with high purity was used.

According to an existing heterogeneous growth scheme, many defects may be generated in a substrate when a single-crystal diamond layer oriented in a (111) direction is formed.

In order to solve the above problem, the present invention proposes an R-plane sapphire substrate as the base layer 100. According to one embodiment of the present invention, the R-plane sapphire substrate may correspond to a sapphire substrate having a top surface oriented in a (1-102) direction. As shown in FIG. 2A and FIG. 2B, the sapphire substrate may have a hexagonal close-packed structure (HCP) structure. Due to the above structure, the sapphire substrate may have no phase change from extremely low temperatures to ultra-high temperatures so as to have excellent mechanical properties while being stable with respect to a temperature, so that the sapphire substrate may be suitable as a substrate for heterogeneous growth.

In more detail, as shown in FIG. 2A, the R-plane sapphire substrate may correspond to a sapphire substrate having a crystal plane, which is inclined at an angle of 35.5 degrees based on a c-axis of a sapphire crystal structure, as a top surface. In particular, the R-plane sapphire substrate may have higher mechanical strength and thermal stability than sapphire substrates oriented in other plane directions, which may mean that the R-plane sapphire substrate is more suitable for high-temperature and high-stress fields such as heterogeneous growth. According to one embodiment of the present invention, when the R-plane sapphire substrate is used as the base layer 100 to arrange the buffer layer 200, an in-plane defect of the buffer layer 200 may be controlled.

Meanwhile, according to one embodiment of the present invention, an Ir metal layer may be formed on a top surface of an R-plane sapphire substrate, so that a defect of the Ir metal layer may be controlled. The above effect may be recognized through experimental results such as an X-ray diffraction analysis scheme and an X-ray diffraction pole figure, and the experimental results will be shown in the drawings that will be described below.

Meanwhile, the sapphire substrate may have various planes in addition to the R-plane described above, and may have, for example, a C-plane as shown in FIG. 2B. The C-plane sapphire substrate may correspond to a sapphire substrate having a crystal plane, which is inclined at a vertical angle based on a c-axis of a sapphire crystal structure, as a top surface. According to one embodiment of the present invention, when the C-plane sapphire substrate is used as the base layer 100 to arrange the buffer layer 200, an in-plane defect of the buffer layer 200 may not be controlled.

The buffer layer 200 may include an Ir metal layer oriented in a (111) direction. In addition, the buffer layer 200 may have a thickness of 20 nm to 1 μm.

Preferably, the buffer layer 200 may have a thickness of 100 nm to 700 nm. More preferably, the buffer layer 200 may have a thickness of 500 nm.

According to one embodiment of the present invention, the buffer layer 200 may be formed on a top surface of the base layer by using one of a sputtering scheme, an E-beam evaporation scheme, and chemical vapor deposition (CVD) equipment.

According to one embodiment of the present invention, the buffer layer 200 may correspond to a configuration for suppressing generation of defects caused by a difference in lattice constants and thermal expansion coefficients between the base layer 100 and the single-crystal diamond layer 300, which are heterogeneous substrates.

In this case, preferably, the top surface of the buffer layer may be oriented in the (111) direction, and shapes of atoms arranged on the top surface of the buffer layer 200 may correspond to or may be similar to shapes of atoms arranged on a top surface of the single-crystal diamond layer 300 formed on an upper side.

In more detail, as shown in FIG. 3A, the buffer layer 200 may include an Ir metal layer having a face-centered cubic (FCC) structure, and the FCC structure may be configured such that the atoms arranged on the crystal plane in the (111) direction may have a triangular shape. As described above, since the top surface of the buffer layer 200 is oriented in the 111 direction, the atoms arranged on the top surface of the buffer layer 200 may preferably have a triangular shape.

Meanwhile, as shown in FIG. 3B, the single-crystal diamond layer 300 may include a single-crystal diamond layer having a diamond cubic structure, and the diamond cubic structure may be configured such that the atoms arranged on the crystal plane in the (111) direction may have a triangular shape.

As described above, each of top surfaces of a buffer layer 200 and a single-crystal diamond layer 300 may be oriented in a (111) direction so as to allow shapes of atoms arranged on the top surfaces to correspond to each other, so that residual stress of the single-crystal diamond layer 300 caused by a difference in lattice constants and thermal expansion coefficients between the single-crystal diamond layer 300 and a base layer 100 may be minimized so as to improve durability of a single-crystal diamond substrate 1.

The single-crystal diamond layer 300 may be formed on the top surface of the buffer layer 200, and may correspond to a configuration that may be used as a substrate for a semiconductor element and an electronic element.

In general, the single-crystal diamond layer 300 may be manufactured by various manufacturing schemes such as a high-temperature high-pressure scheme, a homogeneous growth scheme, and a heterogeneous growth scheme. The present invention relates to the single-crystal diamond layer 300 that is heterogeneously grown, in which the single-crystal diamond layer 300 according to one embodiment of the present invention may be formed by using one of atomic layer deposition (ALD), CVD, or physical vapor deposition (PVD) equipment, and hot filament-CVD (HF-CVD), micro plasma-CVD (MP-CVD), or RF plasma-CVD (RF-CVD) equipment may be used as the CVD equipment.

According to one embodiment of the present invention, a single-crystal diamond layer 300 may be grown while being oriented in a plane direction corresponding to a plane direction of the buffer layer 200, and the single-crystal diamond substrate 1 may control a defect by the buffer layer 200 and the single-crystal diamond layer 300, which are oriented in the plane directions corresponding to each other.

Accordingly, the single-crystal diamond layer 300 may include a single-crystal diamond layer 300 oriented in the (111) direction. In this case, since the buffer layer 200 is formed on the top surface of the base layer 100, a defect of the single-crystal diamond layer 300 may be controlled.

In other words, according to one embodiment of the present invention, a single-crystal diamond layer 300 may be grown on a top surface of a buffer layer 200 in which a defect is controlled, so that a defect of the single-crystal diamond layer 300 may be controlled, and a buffer layer 200 including an Ir metal layer oriented in a (111) direction may be arranged, so that quality of the single-crystal diamond layer 300 oriented in the (111) direction may be improved.

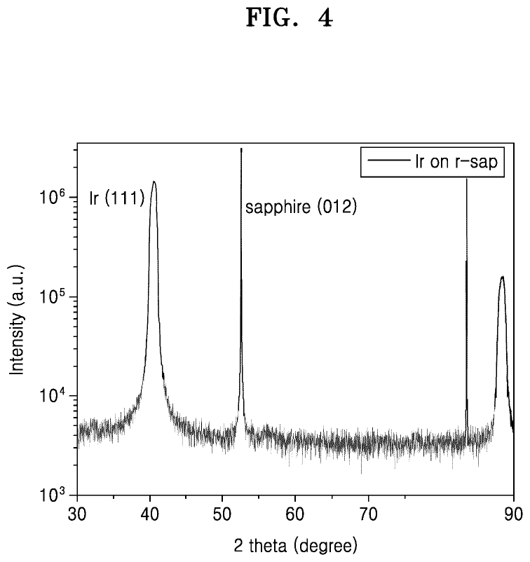

FIG. 4 shows details of X-ray diffraction patterns of a base layer 100 and a buffer layer 200 according to one embodiment of the present invention.

The base layer 100 may be an R-plane sapphire substrate oriented in the (1-102) direction, and the buffer layer 200 may be oriented in the (111) direction.

According to one embodiment of the present invention, the base layer 100 and the buffer layer 200 may exhibit X-ray diffraction patterns as shown in FIG. 4. According to the above patterns, the base layer may have an R-plane sapphire substrate oriented in the (1-102) direction, and the buffer layer 200 may have an Ir metal layer oriented in the (111) direction. In this case, a sapphire (012) peak of FIG. 4 may correspond to the (1-102) direction.

As described above, the base layer 100 and the buffer layer 200 may correspond to layers formed of a single-crystal.

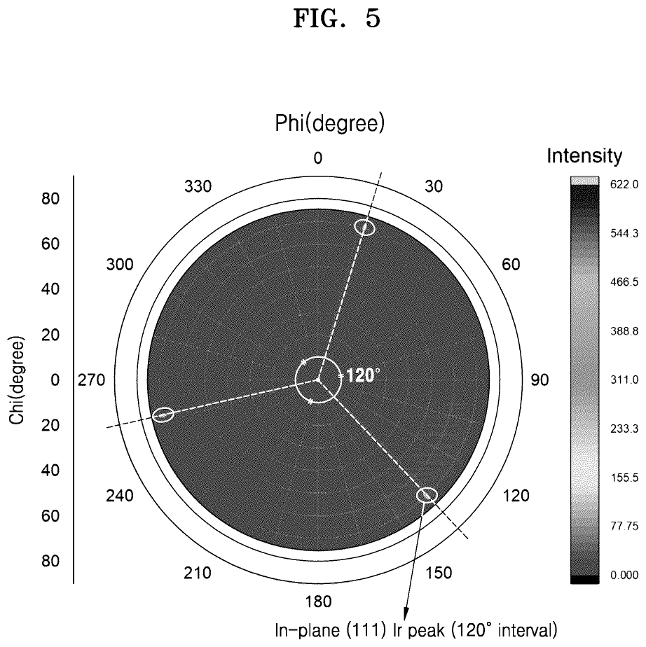

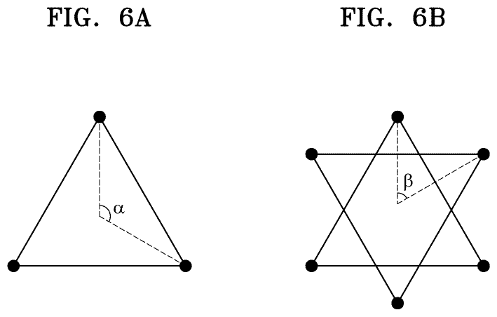

FIG. 5 shows details of an X-ray diffraction pole figure according to one embodiment of the present invention, and FIG. 6A and FIG. 6B schematically show details of a known twin defect.

According to one embodiment of the present invention, the single-crystal diamond substrate 1 may have three peaks spaced apart from each other at an interval of 120 degrees on an X-ray diffraction pole figure.

The X-ray diffraction pole figure may be an analysis scheme that shows in-plane lattice plane direction distribution, and as shown in FIG. 5, the base layer 100 and the buffer layer 200 may have three peaks spaced apart from each other at an interval of 120 degrees on an X-ray diffraction pole figure. This means that no in-plane twin defects are generated in each of the base layer 100 and the buffer layer 200. In other words, this means that the single-crystal diamond layer 300 according to one embodiment of the present invention may be configured such that twin defects are controlled.

In more detail, the twin defect may be a kind of defects that are frequently generated when the single-crystal diamond layer 300 oriented in the (111) direction is grown, and the twin defect may be generated when crystal lattices are oriented in different plane directions within a corresponding plane. As described above, the buffer layer 200 and the single-crystal diamond layer 300 are oriented in the (111) direction, so that the atoms arranged on the top surface in the (111) direction may have a triangular shape. In this case, each of the buffer layer 200 and the single-crystal diamond layer 300 may exhibit an X-ray diffraction pole figure as in FIG. 6A. As shown in FIG. 6A, each of the buffer layer 200 and the single-crystal diamond layer 300 may have α of 120 degrees, which corresponds to an angle between a central axis and peaks, and this means that no in-plane twin defects are generated in the buffer layer 200 and the single-crystal diamond layer 300.

Meanwhile, as shown in FIG. 6B, when β, which corresponds to an angle between a central axis and peaks, has an angle of 60 degrees, this may mean that an in-plane twin defect has been generated in the buffer layer 200 and the single-crystal diamond layer 300. For example, when one plane within a plane of the Ir metal layer included in the buffer layer 200 rotates 60 degrees clockwise based on to the central axis, a peak of an X-ray diffraction pole figure may have a shape as shown in FIG. 6B. In this case, β may have an angle of 60 degrees, and six peaks spaced apart from each other at an interval of 60 degrees on the X-ray diffraction pole figure may be formed. Meanwhile, a difference in the X-ray diffraction pole figures as described above may be caused by relatively high energy required when a defect is generated in the single-crystal diamond layer 300 formed on the R-plane sapphire substrate.

In other words, according to one embodiment of the present invention, a single-crystal diamond layer 300 may be grown on a top surface of a buffer layer 200 in which a defect of a substrate is controlled, so that a defect of the single-crystal diamond layer 300 may be controlled.

Hereinafter, a method for manufacturing a single-crystal diamond substrate 1 according to one embodiment of the present invention will be described in detail.

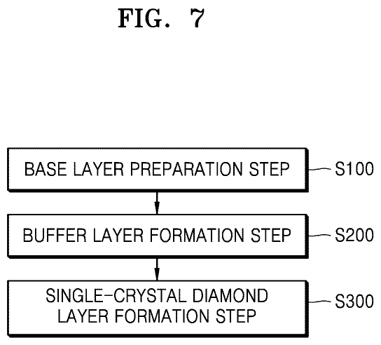

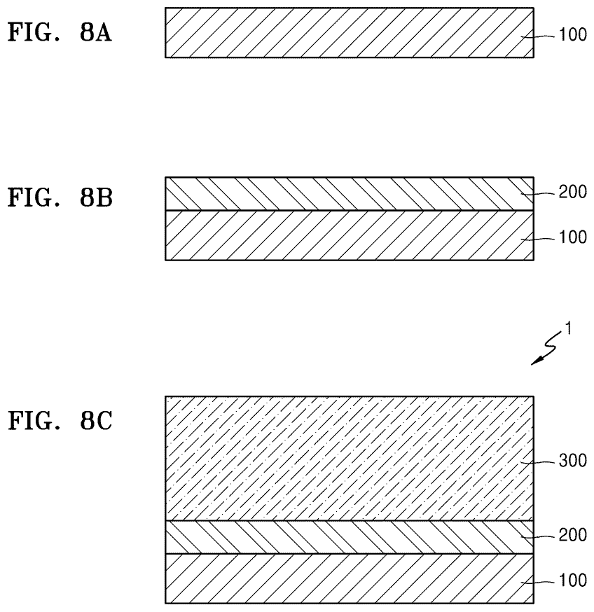

FIG. 7 schematically shows a method for manufacturing a single-crystal diamond substrate 1 according to one embodiment of the present invention, and FIG. 8A, FIG. 8B, and FIG. 8C schematically show an embodiment of performing each step of the method for manufacturing the single-crystal diamond substrate 1 according to one embodiment of the present invention.

Meanwhile, a single-crystal diamond substrate 1 according to one embodiment of the present invention may be formed by the following manufacturing method.

Preferably, the manufacturing method may include: a base layer preparation step S100 of preparing a base layer 100; a buffer layer formation step S200 of forming a buffer layer 200 on the base layer 100; and a single-crystal diamond layer formation step S400 of forming a single-crystal diamond layer 300 on the buffer layer 200, wherein the base layer 100 includes a sapphire substrate, the sapphire substrate has an R-plane oriented in a preset direction, and the buffer layer 200 includes an Ir metal layer.

In the configuration described above, the single-crystal diamond substrate 1 may have three peaks spaced apart from each other at an interval of 120 degrees on an X-ray diffraction pole figure, and may control a twin defect generated upon the formation of the single-crystal diamond layer 300.

In more detail, according to one embodiment of the present invention, in order to form the single-crystal diamond substrate 1, the buffer layer 200 may be formed on a top surface of the base layer 100 as shown in FIG. 8A and FIG. 8B. Thereafter, the single-crystal diamond layer 300 may be formed on a top surface of the buffer layer 200 as shown in FIG. 8C.

In the configuration described above, the buffer layer 200 may be oriented in the (111) direction while a defect of the substrate may be controlled, and the single-crystal diamond layer 300 may be grown on the top surface of the buffer layer 200 in which the defect of the substrate is controlled so that the defect of the substrate may be controlled. In addition, the single-crystal diamond layer 300 may be formed on the top surface of the buffer layer 200, so that residual stress caused by a difference in lattice constants and thermal expansion coefficients between the single-crystal diamond layer 300 and the base layer 100 may be minimized so as to improve durability of the single-crystal diamond substrate 1.

Meanwhile, the single-crystal diamond substrate 1 manufactured by the manufacturing method described above may have a form in which the single-crystal diamond layer 300 is separated from the base layer 100 after the base layer 100, the buffer layer 200, and the single-crystal diamond layer 300 are consecutively formed.

In this case, the single-crystal diamond substrate 1 may be separated from one surface between a top surface of the base layer 100 and a bottom surface of the single-crystal diamond layer 300.

In other words, according to one embodiment of the present invention, the single-crystal diamond substrate 1 may be configured such that the single-crystal diamond layer 300 may be separated from the base layer 100, so that the single-crystal diamond layer 300 may be easily provided.

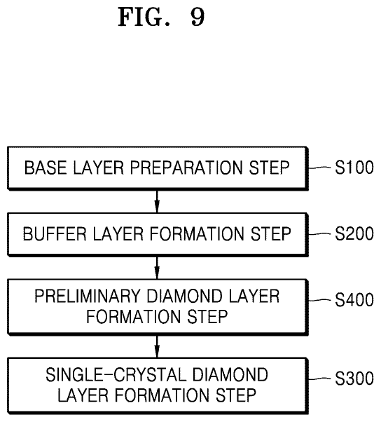

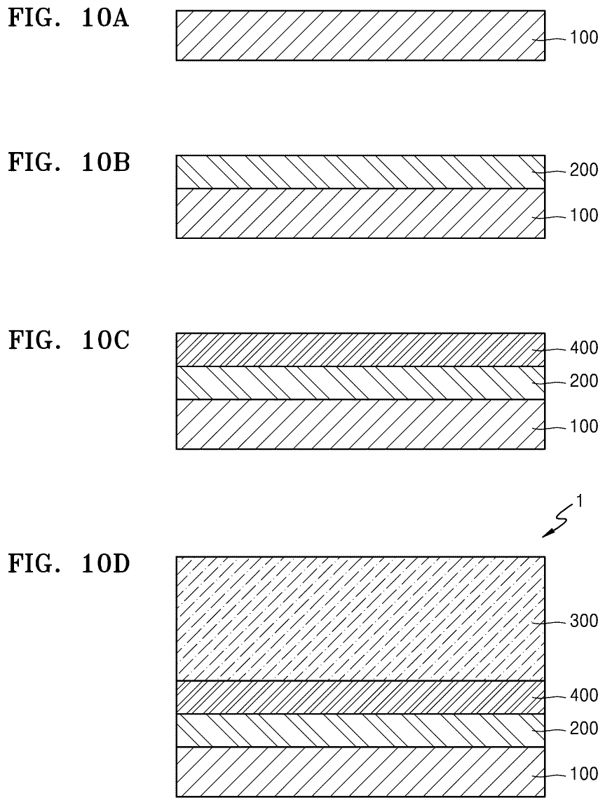

FIG. 9 schematically shows a method for manufacturing a single-crystal diamond substrate 1 according to another embodiment of the present invention, and FIG. 10A, FIG. 10B, FIG. 10C, and FIG. 10D schematically show an embodiment of performing each step of the method for manufacturing the single-crystal diamond substrate 1 according to another embodiment of the present invention.

Meanwhile, the present invention may further include a preliminary diamond layer 400 that assists in a process of forming the single-crystal diamond layer 300. The single-crystal diamond substrate 1 further including the preliminary diamond layer 400 may be formed by the following manufacturing method.

Preferably, the manufacturing method may include: a base layer preparation step S100 of preparing a base layer 100; a buffer layer formation step S200 of forming a buffer layer 200 on the base layer 100; a preliminary diamond layer formation step S400 of forming a preliminary diamond layer 400 on the buffer layer; and a single-crystal diamond layer formation step S300 of forming a single-crystal diamond layer 300 on the preliminary diamond layer 400, wherein the base layer 100 includes a sapphire substrate, the sapphire substrate has an R-plane oriented in a preset direction, and the buffer layer 200 includes an Ir metal layer.

In the configuration described above, the single-crystal diamond substrate 1 may have three peaks spaced apart from each other at an interval of 120 degrees on an X-ray diffraction pole figure, and may control a twin defect generated upon the formation of the single-crystal diamond layer 300.

In addition, in the configuration described above, the single-crystal diamond substrate 1 may further include a preliminary diamond layer 400 formed on the buffer layer 200, the single-crystal diamond layer 300 may be formed on the preliminary diamond layer 400, and the preliminary diamond layer 400 may have a thickness that is thinner than a thickness of the single-crystal diamond layer 300.

In more detail, in order to form the single-crystal diamond substrate 1, the buffer layer 200 may be formed on the top surface of the base layer 100 as shown in FIG. 10A and FIG. 10B. Thereafter, as shown in FIG. 10C, the preliminary diamond layer 400 may be formed on the top surface of the buffer layer 200, and the preliminary diamond layer 400 may serve as a seed of the single-crystal diamond layer 300, so that the single-crystal diamond layer 300 may be easily formed.

In other words, according to one embodiment of the present invention, a preliminary diamond layer 300 that serves as a seed of a diamond layer may be formed on a top surface of a buffer layer 200, so that a yield of the single-crystal diamond layer 300 may be increased.

According to one embodiment of the present invention, a buffer layer including an Ir metal layer may be arranged on a top surface of an R-plane sapphire substrate, and a single-crystal diamond layer may be formed on a top surface of the buffer layer, so that a defect of a single-crystal diamond substrate oriented in a (111) direction may be controlled so as to improve quality.

According to one embodiment of the present invention, an Ir metal layer may be formed on a top surface of an R-plane sapphire substrate, so that a defect of the Ir metal layer may be controlled.

According to one embodiment of the present invention, a single-crystal diamond layer may be grown on a top surface of a buffer layer in which a defect of a substrate is controlled, so that a defect of the single-crystal diamond layer may be controlled.

According to one embodiment of the present invention, each of top surfaces of a buffer layer and a single-crystal diamond layer may be oriented in a (111) direction so as to allow shapes of atoms arranged on the top surfaces to correspond to each other, so that residual stress of the single-crystal diamond layer caused by a difference in lattice constants and thermal expansion coefficients between the single-crystal diamond layer and a base layer may be minimized so as to improve durability of a single-crystal diamond substrate.

According to one embodiment of the present invention, a preliminary diamond layer 300 that serves as a seed of a diamond layer may be formed on a top surface of a buffer layer 200, so that a yield of the single-crystal diamond layer 300 may be increased.

According to one embodiment of the present invention, a single-crystal diamond substrate may be configured such that a single-crystal diamond layer may be separated from a base layer, so that the single-crystal diamond layer may be easily provided.

Although the above description has been made with reference to specific embodiments and drawings, various modifications and changes can be made by a person having ordinary skill in the art from the above description. For example, even when the described techniques are performed in an order that is different from the described manner, and/or the described components such as systems, structures, devices, and circuits are coupled or combined in a form that is different from the described manner, or replaced or substituted by other components or equivalents, appropriate results may be achieved. Therefore, other implementations, other embodiments, and equivalents to the claims are also within the scope of the appended claims.

1. A single-crystal diamond substrate in which a defect of the substrate is controlled, the single-crystal diamond substrate comprising:
a base layer;
a buffer layer formed on the base layer; and
a single-crystal diamond layer formed on the buffer layer,
wherein the base layer includes a sapphire substrate,
the sapphire substrate has an R-plane oriented in a preset direction, and
the buffer layer includes an Ir metal layer.

2. The single-crystal diamond substrate of claim 1, wherein the buffer layer has three peaks spaced apart from each other at an interval of 120 degrees on an X-ray diffraction pole figure.

3. The single-crystal diamond substrate of claim 1, wherein the single-crystal diamond substrate controls a twin defect generated upon the formation of the single-crystal diamond layer.

4. The single-crystal diamond substrate of claim 1, further comprising:
a preliminary diamond layer formed on the buffer layer,
wherein the single-crystal diamond layer is formed on the preliminary diamond layer, and
the preliminary diamond layer has a thickness that is thinner than a thickness of the single-crystal diamond layer.

5. The single-crystal diamond substrate of claim 1, wherein the single-crystal diamond substrate has a form in which the single-crystal diamond layer is separated from the base layer after the base layer, the buffer layer, and the single-crystal diamond layer are consecutively formed.

6. The single-crystal diamond substrate of claim 1, wherein the buffer layer includes the Ir metal layer oriented in a (111) direction.

7. The single-crystal diamond substrate of claim 1, wherein the buffer layer has a thickness of 20 nm to 1 μm.

8. The single-crystal diamond substrate of claim 1, wherein the single-crystal diamond layer is grown while being oriented in a plane direction corresponding to a plane direction of the buffer layer, and
the single-crystal diamond substrate controls a defect of the substrate by the buffer layer and the single-crystal diamond layer, which are oriented in the plane directions corresponding to each other.

9. The single-crystal diamond substrate of claim 6, wherein the single-crystal diamond layer includes a single-crystal diamond layer oriented in the (111) direction.

10. A method for manufacturing a single-crystal diamond substrate in which a defect of the substrate is controlled, the method comprising:
a base layer preparation step of preparing a base layer;
a buffer layer formation step of forming a buffer layer on the base layer; and
a single-crystal diamond layer formation step of forming a single-crystal diamond layer on the buffer layer,
wherein the base layer includes a sapphire substrate, the sapphire substrate has an R-plane oriented in a preset direction, and
the buffer layer includes an Ir metal layer.

11. The method of claim 10, wherein the buffer layer has three peaks spaced apart from each other at an interval of degrees on an X-ray diffraction pole figure.

12. The method of claim 10, wherein the single-crystal diamond substrate controls a twin defect generated upon the formation of the single-crystal diamond layer.

13. A method for manufacturing a single-crystal diamond substrate in which a defect of the substrate is controlled, the method comprising:
a base layer preparation step of preparing a base layer;
a buffer layer formation step of forming a buffer layer on the base layer;
a preliminary diamond layer formation step of forming a preliminary diamond layer on the buffer layer; and
a single-crystal diamond layer formation step of forming a single-crystal diamond layer on the preliminary diamond layer,
wherein the base layer includes a sapphire substrate,
the sapphire substrate has an R-plane oriented in a preset direction, and
the buffer layer includes an Ir metal layer.

14. The method of claim 13, wherein the buffer layer has three peaks spaced apart from each other at an interval of 120 degrees on an X-ray diffraction pole figure.

15. The method of claim 13, wherein the single-crystal diamond substrate controls a twin defect generated upon the formation of the single-crystal diamond layer.
